(19) United States
(12) Patent Application Publication
(10) Pub. No.: US 2025/0171037 A1
(43) Pub. Date: May 29, 2025

(54) QUICK ASSESSMENT OF THE OPERATING STATE OF TECHNICAL SYSTEMS

(71) Applicant: Robert Bosch GmbH, Stuttgart (DE)

(72) Inventors: Peter Bakucz, Klosterlechfeld (DE); Panagiotis Kosioris, Urbach (DE)

(21) Appl. No.: 18/947,753

(22) Filed: Nov. 14, 2024

(30) Foreign Application Priority Data
Nov. 23, 2023 (DE) 10 2023 211 712.6

(51) Int. Cl. B60W 50/023

(52) U.S. Cl. CPC B60W 50/023

(57) ABSTRACT

A method for the assessment of the operating state of a technical system. The operating state is characterized by an aggregate variable whose value results through the interaction of basic variables according to the configuration of the technical system. In the method: an impact function, which indicates dependence of the aggregate variable on the basic variables is provided; the impact function is factorized to form a product of contributions, which depend on different subsets of the basic variables; a graph is formed, each node corresponding to a contribution, an edge extends in relation to each basic variable on which this contribution depends, at least one edge that corresponds to a basic variable on which two or more contributions depend connects two nodes corresponding to such contributions; the Laplace matrix of this graph is ascertained; an extremal eigenvalue of this Laplace matrix is ascertained as the assessment.

### FIELD

The present invention relates to the assessment of the operating state of technical systems, which can, for example, be carried out in advance by simulation with the aim of operating the system optimally.

### BACKGROUND INFORMATION

When operating many technical systems, the quality of the operation is measured using certain characteristic variables. For example, when operating electronic circuits, it is desirable that the temperature of the circuit or of certain components does not exceed a specified value in order not to unduly shorten the service life of capacitors or semiconductor components in particular.

The characteristic variables can generally be measured during operation so that it is possible to respond to the measured values. However, it is desirable to be able to predict values of said characteristic variables for a specific configuration of the technical system in order to be able to take countermeasures earlier in advance, if necessary, or even to be able to optimize the structural design of the technical system with regard to the characteristic variable before the technical system is realized physically. The more complex the relationships that lead to the final value of the characteristic variable are within the technical system, the greater is the computational effort required for a prediction. This in turn affects how far into the future the prediction can reach with a specified budget of computational effort.

### SUMMARY

The present invention provides a method for assessing the operating state of a technical system. The operating state is characterized by at least one aggregate variable Q. The value of this aggregate variable Q results through the interaction of a plurality of basic variables e₁, . . . , eₙ according to the configuration of the technical system. In the example mentioned at the beginning, the temperature of the electronic circuit as the aggregate variable Q results from where in the circuit heat is generated and how this heat is dissipated. This interaction is described by an impact function ƒ(e₁, . . . , eₙ), which indicates the dependence of the aggregate variable Q on the basic variables e₁, . . . , eₙ.

According to an example embodiment of the present invention, the method tarts with providing this impact function ƒ(e₁, . . . , eₙ).

The impact function ƒ(e₁, . . . , eₙ) is subsequently factorized to form a product Πᵢ₌₁^{k}ƒᵢ(Eᵢ) of multiple contributions ƒᵢ(Eᵢ). These contributions ƒᵢ(Eᵢ) depend on different subsets Eᵢ of the basic variables e₁, . . . , eₙ. An impact function ƒ(u,w,x,y,z) can, for example, be written as a product ƒ(u,w,x,y,z)=ƒ₁(u,w,x)·ƒ₂(x,y,z)·ƒ₃(z), where the subsets Eᵢ of the basic variables then are E₁={u,w,x}, E₂={x,y,z}, and E₃={z}. As this example shows, multiple subsets Eᵢ can overlap.

On the basis of this factorization, a graph G is created. The nodes of this graph G correspond to contributions ƒᵢ. The edges of the graph G correspond to basic variables e₁, . . . , eₙ. From each node corresponding to a contribution ƒᵢ, an edge extends in relation to each basic variable e₁, . . . , eₙ on which this contribution ƒᵢ depends. It is not necessary for each edge to connect two nodes. Rather, it is quite possible that an edge starts at one node and that its other end is left open. However, if two or more contributions ƒᵢ depend on one and the same basic variable e₁, . . . , eₙ, at least one edge that corresponds to such a basic variable e₁, . . . , eₙ connects two nodes corresponding to the relevant contributions ƒᵢ. One and the same basic variable e₁, . . . , eₙ can then, for example, be assigned to one or more edges, which each connect two contributions ƒᵢ, and to one or more edges with an open end. The dependence here does not have to be direct (explicit), but can also be implicit, for example via an intermediate result in which the other basic variable in question e₁, . . . , eₙ then again occurs.

Thus, the graph G can in particular be used to represent that, for example, sensor systems for detecting the basic variables e₁, . . . , eₙ can be at least partially redundant. For example, the detection ranges covered by multiple sensors can partially overlap. Accordingly, the values measured by multiple sensors can change in a time-dependent manner and/or there can be time-dependent correlations between these values.

The Laplace matrix L of the graph G is ascertained. On its diagonal, this Laplace matrix L contains the node degrees, which indicate the number of connections of the corresponding node to other nodes. The off-diagonal elements of the Laplace matrix L indicate the adjacencies of the nodes to one another. In particular, the adjacency can include a statement as to whether a connection exists between two given nodes, and this connection can optionally also be weighted. The Laplace matrix L for each graph G is thus unambiguously determined.

An extremal (i.e., maximum or minimum) eigenvalue α of the Laplace matrix L is ascertained as the desired assessment of the operating state.

It has been recognized that this extremal eigenvalue α is proportional to the desired aggregate variable Q and in particular assumes an extremum if and only if Q assumes an extremum. If the assessment of the operating state does not require the exact value of Q, but only a point where Q assumes an extremum, this information can be obtained via the extremum of the eigenvalue α much faster than by calculating the curve of Q and subsequently determining an extremum from this curve. This is based on the idea that only linear transformations are used when simplifying the original relationship Q=ƒ(e₁, . . . , eₙ) to the extremum of the eigenvalue α. The simplification does not affect the accuracy with which the position of the extremum can be determined depending on any variables. At the same time, the simplification also introduces a level of abstraction so that dependencies on unimportant details of the technical system are eliminated from the start.

If not only the location of the extremum is required, but also the maximum or minimum value of the aggregate variable Q, this value at the location of the extremum can be calculated directly from the basic variables e₁, . . . , eₙ by means of the conventional method. This is comparatively computationally intensive, but this effort only occurs once at the location of the extremum, whereas it was previously already incurred many thousands of times when searching for the extremum. The saving in computing time is thus hardly reduced by the one-time explicit evaluation of Q.

The much faster evaluation of the extremal eigenvalue α is in particular advantageous if the question is how the aggregate variable Q changes depending on the configuration of the technical system. In particular, in many applications of technical systems, the question is how the configuration of the technical system is to be designed in order to achieve an optimal value of the aggregate variable Q. The search for a corresponding optimum requires a plurality of evaluations as to the direction in which the aggregate variable Q moves in response to certain changes in the configuration. If it were required to evaluate Q explicitly on the basis of the impact function Q=ƒ(e₁, . . . , eₙ) each time, this would take too long.

In a particularly advantageous example embodiment of the present invention, a plurality of candidate configurations of the technical system are set up, which differ in values of the basic variables e₁, . . . , eₙ and/or in the interaction of these basic variables e₁, . . . , eₙ resulting in the aggregate variable Q. The resulting operating state is then assessed for each of these candidate configurations.

This makes it possible to ascertain the candidate configuration that leads to the best operating state. In particular, the quick assessment of the operating state via the extremal eigenvalue α can be used as feedback for the optimization of at least one value of a basic variable e₁, . . . , eₙ and/or of the interaction of at least two basic variables e₁, . . . , eₙ. Since the optimization is aimed at improving the assessment of the operating state resulting from the thus-changed configuration of the technical system, the assessment must be calculated quite often. This is in particular true in light of the fact that gradient-based optimization methods cannot be used. It is a major advantage of gradient-based methods that the evaluations of the objective function (here: the impact function ƒ) can be planned in a targeted manner so that the total number of these evaluations can be advantageously reduced. However, the optimization of the candidate configuration required here is a mixed integer problem because, in many respects, the candidate configuration cannot be optimized continuously, but only discretely. For example, it is possible to install two or three fans, but not 2.5 fans.

In order to generate new configurations of the technical system, at least one component of the technical system in another advantageous example embodiment of the present invention is
replaced with another component, and/or
placed at a location, and/or
controlled differently.

For example, a component that releases heat can be replaced with a component that releases less heat. Conversely, for example, a heat-sensitive component can be replaced with a less heat-sensitive component so that a higher temperature can be permitted in its environment.

By placing a heat-generating component at a different location in the technical system, the aim can, for example, be to ensure that the heat of the component can be better dissipated from this other location so that this heat does not build up. Conversely, a fan or other cooling element, such as a vapor chamber, can, for example, be positioned such that it can dissipate the most heat.

Such problems can, for example, occur when configuring PCs. For example, if the configuration already contains many components and a powerful graphics card, adding another SSD mass storage device at a distance where it appears to have nothing to do with the graphics card can have the effect that heat released by the graphics card builds up on the SSD mass storage device and that both components are ultimately overheated.

For example, a component can also be controlled differently with the aim that it generates less heat. For example, the heat released by a processor increases in a highly nonlinear manner with the clock frequency at which the processor operates. In a frequency converter with pulse width modulation, the power loss, and thus the heat produced, depends strongly on the switching frequency and the modulation level of the pulse width modulation.

According to an example embodiment of the present invention, particularly advantageously, a candidate configuration with the best assessment of the resulting operating state, and/or an optimal configuration found during the optimization, is implemented in the hardware of the technical system. This ensures that the advantages of the selected configuration actually manifest in the operating state of the physical system. The implementation in the hardware can, for example, in particular include that the technical system is assembled from hardware components on the basis of the selected configuration and that these hardware components are spatially arranged according to the selected configuration.

According to the statements above, the aggregate variable Q in a particularly advantageous embodiment is a measure of at least one heat flow to be transported within the technical system or out of the technical system, and/or of at least one temperature at a specified location within the technical system. Especially with regard to these thermal variables, a quick analysis by simulation using the extremal eigenvalue α is advantageous because the experimental analysis in the laboratory would be extremely time-consuming due to the inertia of cooling and heating processes at the heat capacities in the system.

Accordingly, at least one basic variable e₁, . . . , eₙ can, for example, in particular represent a heat flow from a heat source, a heat flow into a heat sink, and/or a measure of a thermal conductivity, and/or a transport capacity for a heat flow within the technical system.

In another particularly advantageous example embodiment of the present invention, the aggregate variable Q is a measure of the probability with which at least one undesirable event, such as a “system failure”, occurs in the technical system. The method can also be used to evaluate a fault tree, which leads to the undesirable event, much more quickly. This in turn can be used in the manner described above in order, for example, to optimize the configuration of the technical system such that the probability with which the undesirable event occurs is minimized. Analogously to what was said above, the evaluation of the extremum via the extremal eigenvalue α does not directly result in the probability as an aggregate variable Q. However, it is of no consequence to evaluate the probability once again explicitly according to a conventional method for this one case, after many thousands of such evaluations were saved beforehand.

For these and similar applications, it is thus particularly advantageously possible to provide an impact tree W whose nodes correspond to basic variables and whose connections between nodes correspond to logical operations of the basic variables within the framework of the interaction resulting in the aggregate variable. The impact function ƒ(e₁, . . . , eₙ) can then be ascertained using this impact tree W. This impact tree W is not to be confused with the Lambert-Omega function, which is often denoted by the same letter.

In another particularly advantageous example embodiment of the present invention, the basic variables e₁, . . . , eₙ include basic probabilities of basic events which, individually or in combination, can cause the undesirable event to occur in the technical system. The logical interaction of the basic events up to the possible occurrence of the undesirable event is defined by a configuration of the technical system. This configuration can, for example, in particular define logical dependencies and mechanisms of action as to the extent to which the interaction of multiple basic events, possibly via one or more intermediate stages, ultimately leads to the occurrence of the undesirable event. The impact tree W can then be understood as a fault tree. The method can then be used to provide a quick approximation for the known fault tree analysis. The fault tree analysis is always more accurate but significantly slower to calculate by means of conventional methods. The approximation character lies in the simplifying assumptions on the basis of which the impact function is factorized: In reality, the fault tree also contains contributions that are not captured by the model of the factor graph. These contributions are neglected in the calculation with the factor graph, just as, for example, perturbation theory or linearization neglects certain contributions. The gain in speed depends on the clever choice of the specific factorization.

In a particularly advantageous example embodiment of the present invention, at least one basic probability is defined as a membership function of at least one state variable of the technical system and/or its environment and/or as a function of at least one other basic probability. These basic probabilities are also called fuzzy probabilities. This turns the fault tree into a fuzzy fault tree. A certain proportion of the basic probabilities consisting of fuzzy probabilities does not necessarily affect the basic implementation of the method described here. However, the usefulness of the method increases significantly once again because the method saves evaluations of basic probabilities and the evaluation of fuzzy probabilities is particularly “expensive” in terms of computational effort. The potential gain in speed when approximating fuzzy fault trees by means of the factor graph is thus even greater than when approximating conventional fault trees.

Furthermore, the evaluation of the desired probability for the occurrence of the undesirable event is once again significantly faster, especially in the case of a fault tree with fuzzy probabilities, than a conventional evaluation according to the “minimal cut set” method. Even if the technical system is only of moderate size and has about 100 different components, there can already be thousands of “cut sets” of basic events that together can cause the undesirable event. These “cut sets” would all need to be checked as to whether they are minimal. Such an analysis must take into account both technical propagation of a fault from one component to the next and statistical dependencies between components and common causes for multiple, apparently independent failures.

The basic events can, for example, in particular be redundant. Redundancy on the one hand can, for example, be implemented in that multiple components or assemblies, which can complement or replace one another, are used to provide a specific functionality. This redundancy can, for example, in particular be implemented as “hot redundancy”, in which the multiple components or assemblies are always active at the same time. This is the case mainly considered here specifically for the purposes of at least partially automated driving. There is also “cold redundancy”, in which another component or assembly only becomes active as needed in the event of failure or malfunction of an active component or assembly. An example in this respect is emergency diesel generators, which are only activated in the event of a power failure.

However, redundancy can also be implemented, for example, in that one and the same component or assembly is relevant at multiple stages of a causal chain leading to an undesirable event.

All types of redundancy listed here can also occur in a mixed form in one and the same technical system.

The assessment of the operating state on the basis of variables other than the probability of an undesirable event can also be understood on the basis of the fuzzy fault tree. Here, each entity corresponding to a node in the fault tree has a state vector. The membership functions in the fuzzy fault tree indicate for each entity (such as a device or a component) to what extent this entity is important for the overall state of the system. In particular, the interaction of multiple influences on an entity can be modeled in the form of membership functions. Accordingly, during the optimization of the configuration of the technical system, the membership functions can also be optimized in order ultimately to improve the physical interaction.

In this way, it can be determined, for example, that the lack of heat resistance of a particular electrolytic capacitor is a significant factor for the overall failure probability of the technical system. The reliability of this system can then be significantly improved by replacing this electrolytic capacitor with one of higher quality.

For example, a fuzzy fault tree can thus be created for the reliability of the thermal management in a device that has heat sources (such as CPUs or GPUs) and is monitored by a plurality of temperature sensors. The reliability can then, for example, be defined via the probability of the undesirable event “system failure,” which in turn can be caused by basic events, such as exceeding a maximum permissible temperature on certain components. The basic probabilities with which the basic events occur can then, for example, depend on the measured values of the temperature sensors. The method proposed here can then be used to investigate particularly quickly which changes to the configuration of the system reduce the probability of system failure.

In a particularly advantageous example embodiment of the present invention, a control unit for a vehicle is selected as the technical system. Such devices are safety-relevant components of the vehicle and must therefore be certified in a comparatively complex process. It is therefore advantageous to optimize the control unit in the computer by means of the method described here, before it is physically realized and then certified. If insufficient performance in relation to the aggregate variable Q emerges later and the device needs to be reworked, this could invalidate the certification. The work effort and financial investment for the certification would then be incurred again.

Furthermore, the question of heat dissipation, which is an important application of the method proposed here, is a difficult topic, especially for control units, since the installation space and thus the possibilities for heat dissipation are very limited.

This in particular applies in another particularly advantageous embodiment in which the control unit is designed to control at least partially automated driving functions of the vehicle. This application often makes it necessary to use hardware accelerators, such as GPUs, for evaluating neural networks. Such hardware accelerators generate a particularly large amount of heat.

The method of the present invention can in particular be wholly or partially computer-implemented. The present invention therefore also relates to a computer program comprising machine-readable instructions that, when executed on one or more computers and/or compute instances, cause the computer(s) and/or compute instances to execute the disclosed method of the present invention. In this sense, control devices for vehicles and embedded systems for technical devices, which are also capable of executing machine-readable instructions, are also to be regarded as computers. Compute instances can be virtual machines, containers or serverless execution environments, for example, which can be provided in a cloud in particular.

The present invention also relates to a machine-readable data carrier and/or to a download product comprising the computer program of the present invention. A download product is a digital product that can be transmitted via a data network, i.e., can be downloaded by a user of the data network, and can, for example, be offered for immediate download in an online shop.

Furthermore, one or more computers and/or compute instances can be equipped with the computer program, with the machine-readable data carrier, or with the download product.

Further measures improving the present invention are explained in more detail below, together with the description of the preferred exemplary embodiments of the present invention, with reference to the figures.

### BRIEF DESCRIPTION OF THE DRAWINGS

FIG. 1 shows an exemplary embodiment of the method 100 for the assessment 2 of the operating state of a technical system 1, according to the present invention.

FIG. 2 shows an exemplary path from a fuzzy fault tree to the evaluation of the operating state via the extremal eigenvalue α, according to an example embodiment of the present invention.

FIG. 3 shows a control unit for a vehicle as an exemplary technical system 1 for the application of the method 100, according to an example embodiment of the present invention.

### DETAILED DESCRIPTION OF EXAMPLE EMBODIMENTS

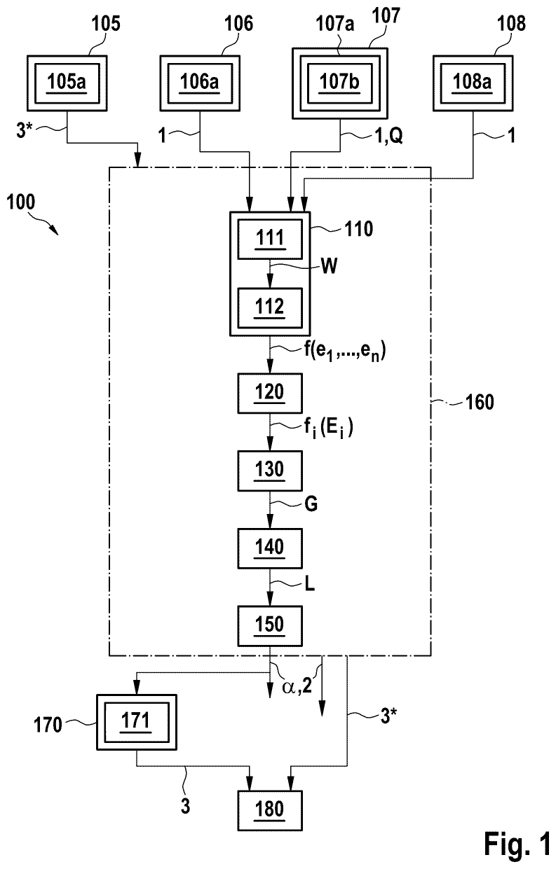

FIG. 1 is a schematic flowchart of an exemplary embodiment of the method 100 for the assessment 2 of the operating state of a technical system 1. The operating state is characterized by at least one aggregate variable Q whose value results through the interaction of a plurality of basic variables e₁, . . . , eₙ according to the configuration (3) of the technical system.

According to block 106, the aggregate variable Q can be a measure of at least one heat flow to be transported within the technical system 1 or out of the technical system 1, and/or of at least one temperature at a specified location within the technical system 1. For example, according to block 106a, at least one basic variable e₁, . . . , eₙ can then, for example, represent a heat flow from a heat source, a heat flow into a heat sink, and/or a measure of a thermal conductivity, and/or a transport capacity for a heat flow within the technical system.

According to block 107, the aggregate variable Q can be a measure of the probability with which at least one undesirable event occurs in the technical system 1. According to block 107a, the basic variables e₁, . . . , eₙ can then include basic probabilities of basic events which, individually or in combination, can cause the undesirable event to occur in the technical system 1. At least one basic probability can then be defined according to block 107b as a membership function of at least one state variable of the technical system 1 and/or its environment and/or as a function of at least one other basic probability.

According to block 108, a control unit for a vehicle can be selected as the technical system 1. According to block 108a, the control unit can then be designed to control at least partially automated driving functions of the vehicle.

In step 110, an impact function ƒ(e₁, . . . , eₙ), which indicates the dependence of the aggregate variable Q on the basic variables e₁, . . . , eₙ, is provided.

According to block 111, an impact tree W can be provided, whose nodes correspond to basic variables and whose connections between nodes correspond to logical operations of the basic variables within the framework of the interaction resulting in the aggregate variable. Here, the desired aggregate variable Q is at the root of the impact tree W.

According to block 112, the impact function ƒ(e₁, . . . , eₙ) can then be ascertained using this impact tree W.

In step 120, the impact function ƒ(e₁, . . . , eₙ) is factorized to form a product Πᵢ₌₁^{k}ƒᵢ(Eᵢ) of multiple contributions ƒᵢ(Eᵢ), which depend on different subsets Eᵢ of the basic variables e₁, . . . , eₙ.

In step 130, a graph G, whose nodes correspond to contributions ƒᵢ and whose edges correspond to basic variables e₁, . . . , eₙ, is created. From each node corresponding to a contribution ƒᵢ, an edge extends in relation to each basic variable e₁, . . . , eₙ on which this contribution ƒᵢ depends. Furthermore, at least one edge that corresponds to a basic variable e₁, . . . , eₙ on which two or more contributions ƒᵢ depend connects two nodes corresponding to such contributions ƒᵢ.

In step 140, the Laplace matrix L of the graph G is ascertained. This matrix is unambiguously determined.

In step 150, an extremal eigenvalue α of the Laplace matrix L is ascertained as the desired assessment 2 of the operating state.

According to block 105, a plurality of candidate configurations 3* of the technical system 1 can be set up. These candidate configurations 3* differ in values of the basic variables e₁, . . . , eₙ and/or in the interaction of these basic variables e₁, . . . , eₙ resulting in the aggregate variable Q. The resulting operating state can then be assessed according to block 160 for each of these candidate configurations 3*.

In the example shown in FIG. 1, in step 170, at least one value of a basic variable e₁, . . . , eₙ, and/or the interaction of at least two basic variables e₁, . . . , eₙ, is optimized with the aim of improving the assessment 2 of the operating state resulting from the thus-changed configuration 3 of the technical system.

In this case, according to blocks 105a and 171, at least one new configuration 3 of the technical system 1 can, for example, in particular be generated by at least one component of the technical system 1 being
replaced by another component, and/or
placed at a location, and/or
controlled differently.

In the example shown in FIG. 1, in step 180, a candidate configuration 3* with the best assessment of the resulting operating state, and/or an optimal configuration 3 found during the optimization, is implemented in the hardware of the technical system 1.

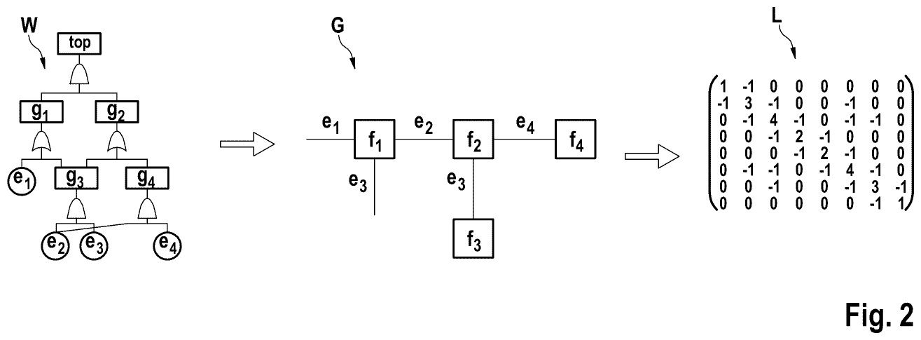

FIG. 2 illustrates the path from a fuzzy fault tree as the impact tree W to the evaluation of the operating state via the extremal eigenvalue α. The impact tree W contains basic events e₁, e₂, e₃, and e₄, each of which is assigned a basic probability for its occurrence. The basic events e₁, e₂, e₃, and e₄ are linked to one another via logic gates, which produce intermediate results g₁, g₂, g₃, and g₄. These intermediate results g₁, g₂, g₃, and g₄ can be regarded as composite events which can have a specific technical meaning in the context of the technical system 1. For example, g₃ the probability of a fan problem can be general and can be a composite of the basic probabilities e₂ and e₃ for the failure of specific fans in each case. At the top of the impact tree W is the undesirable event whose probability is to be evaluated or reduced.

When transforming the impact tree W into the graph G, the basic events e₁, e₂, e₃, and e₄ and the logic gates that link these basic events e₁, e₂, e₃, and e₄ to one another reverse their roles in a way. The nodes of the graph G correspond to gate functions ƒ₁, ƒ₂, ƒ₃, and ƒ₄, which calculate the intermediate results g₁, g₂, g₃, and g₄. The intermediate steps of first ascertaining the impact function ƒ(e₁, . . . , eₙ) from the impact tree W and then factorizing it into contributions ƒᵢ(Eᵢ) are not shown in FIG. 2 for the sake of clarity.

In the example shown in FIG. 2, the function ƒ₁ depends directly on e₁ and indirectly, via g₃, on e₂ and e₃. The function ƒ₂ depends indirectly, via g₃ and g₄, on e₂, e₃ and e₄. This also covers the fact that g₃ as such depends on e₂ and g₄ as such depends on e₂. It is noted via an edge between ƒ₂ and ƒ₃ that both ƒ₂ and ƒ₃ depend on e₃. In the same way, it is noted via an edge between ƒ₂ and ƒ₄ that both ƒ₂ and ƒ₄ depend on e₄. Accordingly, ƒ₁ and ƒ₂ are also connected via an edge corresponding to e₂.

From the graph G, the Laplace matrix L unambiguously follows, whose extremal eigenvalue α can be used as an assessment of the operating state of the technical system 1.

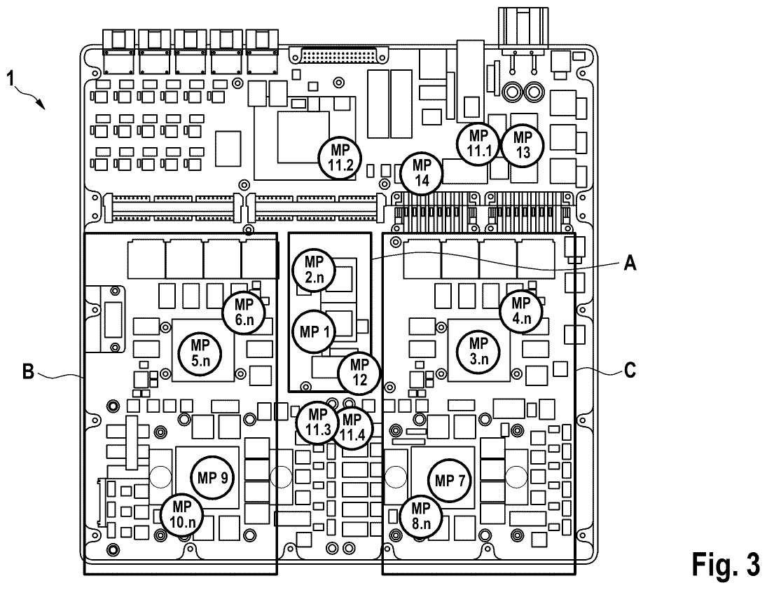

FIG. 3 shows, by way of example, a control unit for automated driving functions of a vehicle as a technical system 1, the operating state of which can be easily evaluated by means of the method 100. FIG. 3 shows the side of the circuit board that is equipped with active components. The circuit inter alia comprises hardware accelerators A, B, and C for specific functions, such as the inference of neural networks. Distributed across the circuit board are numbered measuring points (MP), where the local temperature is measured. On the back side of the circuit board (not shown in FIG. 3), there is a vapor chamber as a passive cooling element.

1-19. (canceled)

20. A method for an assessment of an operating state of a technical system, wherein the operating state is characterized by at least one aggregate variable whose value results through an interaction of a plurality of basic variables according to a configuration of the technical system, the method comprising the following steps:
providing an impact function, which indicates a dependence of the aggregate variable on the basic variables;
factorizing the impact function to form a product of multiple contributions, which depend on different subsets of the basic variables;
creating a graph, whose nodes correspond to the contributions and whose edges correspond to the basic variables, wherein
from each node corresponding to a contribution, an edge extends in relation to each of the basic variables on which the contribution depends, and
at least one edge that corresponds to a basic variable on which two or more of the contributions depend connects two nodes corresponding to the two of more contributions;
ascertaining a Laplace matrix of the graph; and
ascertaining an extremal eigenvalue of the Laplace matrix as the assessment of the operating state.

21. The method according to claim 20, wherein:
a plurality of candidate configurations of the technical system are set up, which differ in values of the basic variables and/or in an interaction of the basic variables resulting in the aggregate variable; and
a resulting operating state is assessed for each of the candidate configurations.

22. The method according to 20, wherein at least one value of a basic variable, and/or an interaction of at least two basic variables, is optimized with an aim of improving the assessment of the operating state resulting from a changed configuration of the technical system.

23. The method according to claim 21, wherein at least one new configuration of the technical system is generated by at least one component of the technical system being:
replaced by another component, and/or
placed at a location, and/or
controlled differently.

24. The method according to claim 23, wherein a candidate configuration with a best assessment of the resulting operating state, and/or an optimal configuration found during the optimization, is implemented in hardware of the technical system.

25. The method according to claim 20, wherein the aggregate variable is a measure of: (i) at least one heat flow to be transported within the technical system or out of the technical system, and/or (ii) of at least one temperature at a specified location within the technical system.

26. The method according to claim 25, wherein at least one of the basic variables represents a heat flow from a heat source, and/or a heat flow into a heat sink, and/or a measure of a thermal conductivity, and/or a transport capacity for a heat flow within the technical system.

27. The method according to claim 20, wherein the aggregate variable is a measure of a probability with which at least one undesirable event occurs in the technical system.

28. The method according to claim 27, wherein the basic variables include basic probabilities of basic events which, individually or in combination, can cause the undesirable event to occur in the technical system.

29. The method according to claim 28, wherein at least one of the basic probabilities is defined as a membership function of at least one state variable of the technical system and/or its environment and/or as a function of at least one other of the basic probabilities.

30. The method according to claim 29, wherein redundant basic events are selected.

31. The method according to claim 30, wherein a redundancy of basic events in the technical system is implemented in that multiple components or assemblies, which can complement or replace one another, are used to provide a specific functionality.

32. The method according to claim 31, wherein the redundancy in the technical system is realized as:
hot redundancy to the extent that the multiple components or assemblies that provide one and the same functionality are always active at the same time, and/or
cold redundancy to the extent that another component or assembly only becomes active as needed in the event of failure or malfunction of an active component or assembly.

33. The method according to claim 30, wherein a redundancy of basic events in the technical system is implemented in that one and the same component or one and the same assembly is relevant at multiple stages of a causal chain leading to an undesirable event.

34. The method according to claim 20, wherein the technical system is a control unit for a vehicle.

35. The method according to claim 34, wherein the control unit is configured to control at least partially automated driving functions of the vehicle.

36. The method according to claim 20, wherein:
an impact tree is provided, whose nodes correspond to the basic variables and whose connections between nodes correspond to logical operations of the basic variables in a framework of an interaction resulting in the aggregate variable, wherein the aggregate variable is at a root of the impact tree, and
the impact function is ascertained using this impact tree.

37. Computer program containing machine-readable instructions that, when executed on one or more computers and/or compute instances, cause the computer(s) and/or compute instances to execute the method (100) according to one of claims 1 to 17.

38. A non-transitory machine-readable data carrier on which is stored a computer program including machine-readable instructions for an assessment of an operating state of a technical system, wherein the operating state is characterized by at least one aggregate variable whose value results through an interaction of a plurality of basic variables according to a configuration of the technical system, the instructions, when executed by one or more computers and/or compute instance, cause the one or more computers and/or compute instance to perform the following steps:
providing an impact function, which indicates a dependence of the aggregate variable on the basic variables;
factorizing the impact function to form a product of multiple contributions, which depend on different subsets of the basic variables;
creating a graph, whose nodes correspond to the contributions and whose edges correspond to the basic variables, wherein
from each node corresponding to a contribution, an edge extends in relation to each of the basic variables on which the contribution depends, and
at least one edge that corresponds to a basic variable on which two or more of the contributions depend connects two nodes corresponding to the two of more contributions;
ascertaining a Laplace matrix of the graph; and
ascertaining an extremal eigenvalue of the Laplace matrix as the assessment of the operating state.
